(19) United States
(12) Patent Application Publication
(10) Pub. No.: US 2021/0098724 A1
(43) Pub. Date: Apr. 1, 2021

(54) THIN FILM TRANSISTOR

(71) Applicant: INDUSTRY-UNIVERSITY COOPERATION FOUNDATION HANYANG UNIVERSITY, Seoul (KR)

(72) Inventors: Myung Mo SUNG, Seoul (KR); Jong Chan KIM, Paju-si (KR); Sung Ho YU, Seoul (KR)

(73) Assignee: INDUSTRY-UNIVERSITY COOPERATION FOUNDATION HANYANG UNIVERSITY, Seoul (KR)

(21) Appl. No.: 17/039,213

(22) Filed: Sep. 30, 2020

(30) Foreign Application Priority Data
Oct. 1, 2019 (KR) 10-2019-0121854
May 26, 2020 (KR) 10-2020-0062823
Sep. 18, 2020 (KR) 10-2020-0120477

(51) Int. Cl. H01L 51/05; H01L 29/49; H01L 29/15

(52) U.S. Cl. CPC H01L 51/0558; H01L 29/152; H01L 29/4908; H01L 51/0529

(57) ABSTRACT

A thin film transistor according to the inventive concept includes: a substrate; an insulating layer provided on the substrate; a superlattice channel layer provided on the insulating layer; and a source electrode and a drain electrode configured to cover a pair of opposite lateral surfaces of the superlattice channel layer, wherein the superlattice channel layer includes alternately stacked semiconductor layers and organic layers. A thickness of each semiconductor layer may be greater than about 3 nm to less than about 5 nm, and a thickness of each organic layer may be about 1 Å to about 1 nm.

### CROSS-REFERENCE TO RELATED APPLICATIONS

This U.S. non-provisional patent application claims priority under 35 U.S.C. § 119 of Korean Patent Application Nos. 10-2019-0121854, filed on Oct. 1, 2019, 10-2020-0120477, filed on Sep. 18, 2020, and 10-2020-0062823, filed on May 26, 2020, the entire contents of which are hereby incorporated by reference.

### BACKGROUND

The present disclosure herein relates to a thin film transistor, and more particularly, to a thin film transistor including a superlattice channel layer.

Recently, organic-inorganic hybrid materials get the limelight in various fields. The organic-inorganic hybrid materials are widely used as materials capable of improving optical properties, magnetic properties, light-emitting properties, electrical properties, ionic conductivity properties, chemical reactivity, etc. However, the organic-inorganic hybrid materials have limited use due to structural irregularity and some incompatible properties between organic material and inorganic material components. Accordingly, numerous studies for overcoming the limitations have been conducted utilizing a superlattice structure with periodically repeated organic layers and inorganic layers.

### SUMMARY

The task for solving of the present disclosure is to provide a thin film transistor having improved operation reliability and electrical properties.

Another task for solving of the present disclosure is to provide a thin film transistor having excellent mechanical flexibility.

The task for solving of the present disclosure is not limited to the aforementioned tasks, and unreferred other tasks may be clearly understood by a person skilled in the art from the description below.

An embodiment of the inventive concept provides a thin film transistor including: a substrate; an insulating layer provided on the substrate; a superlattice channel layer provided on the insulating layer; and a source electrode and a drain electrode configured to cover a pair of opposite lateral surfaces of the superlattice channel layer, wherein the superlattice channel layer includes alternately stacked semiconductor layers and organic layers, a thickness of each semiconductor layer is greater than about 3 nm to less than about 5 nm, and a thickness of each organic layer is about 1 Å to about 1 nm.

In an embodiment, the semiconductor layers may include first to third semiconductor layers, which are separated vertically, the organic layers may include first to fourth organic layers, which are separated vertically, and a ratio of a thickness of any one among the organic layers with respect to a thickness of any one among the semiconductor layers may be about 0.1 to about 0.25.

In an embodiment, the semiconductor layers may include a metal oxide or a transition metal dichalcogenide.

In an embodiment, the organic layer may include a material represented by Formula 1 below.

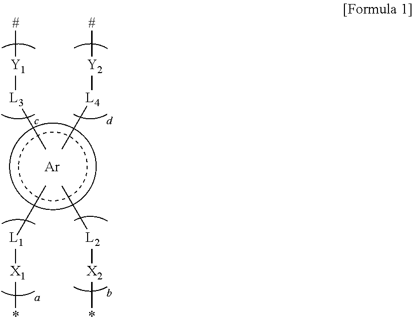

In Formula 1, X₁, X₂, Y₁, and Y₂ are each independently O, S, Se, NH, or PH, * is a part combined with a top of the insulating layer or a top of any one among adjacent semiconductor layers, # is a part combined with a bottom of any other one among adjacent semiconductor layers, each of a, b, c, and d is 1 or 0, where a+b is 1 or more, and c+d is 1 or more, Ar is a functional group comprising at least one aromatic group, and each of L₁, L₂, L₃ and L₄ is an alkylene group of 1 to 3 carbon atoms.

In an embodiment, the source electrode may include a first part provided on a top of the superlattice channel layer, and a second part connected with the first part and extended in parallel to the lateral surface of the superlattice channel layer, and the second part of the source electrode may be in contact with the lateral surfaces of the semiconductor layers.

In an embodiment, the drain electrode may include a first part provided on the top of the superlattice channel layer, and a second part connected with the first part and extended in parallel to the lateral surface of the superlattice channel layer, the first part of the source electrode and the first part of the drain electrode may be separately disposed horizontally, and a separating distance between the first part of the source electrode and the first part of the drain electrode may be about 200 um to about 400 um.

In an embodiment, the superlattice channel layer may include any one among structures of organic layer/[semiconductor layer/organic layer]ₙ, [semiconductor layer/organic layer]ₙ, organic layer/[semiconductor layer/organic layer]ₙ₊₁/Semiconductor layer, and [semiconductor layer/organic layer]n+1/semiconductor layer, where n is 2 or 3.

In an embodiment, the thin film transistor may have one threshold voltage, and with the application of a higher voltage than the threshold voltage to the substrate, charges may be configured to move horizontally along each semiconductor layer.

In an embodiment, the semiconductor layers may be amorphous semiconductor, and a dielectric constant of each semiconductor layer may be about 2 to about 6.

In an embodiment, a flexible film provided on a bottom of the substrate may be further included, numbers of the superlattice channel layers may be provided on the flexible film, and the flexible film may include polyethylene terephthalate (PET) or polyimide (PI).

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view of a thin film transistor according to exemplary embodiments of the inventive concept;

FIG. 2 is a cross-sectional view cut along line I-I′ in FIG. 1;

FIG. 3 is a diagram for explaining a thin film transistor according to exemplary embodiments of the inventive concept;

FIG. 4 is a photographic image observed with a transmission electron microscope on the cross-section of a superlattice channel layer according to Experimental Example 1;

FIG. 5 shows analysis results on the semiconductor layer of a superlattice channel layer according to Experimental Example 1 through an X-ray diffraction observation method;

FIG. 6 is a graph showing field mobility in accordance with operation temperature conditions of thin film transistors according to Experimental Example 1 and Comparative Example; and

FIG. 7 and FIG. 8 show graphs showing transfer properties, threshold voltage and charge mobility in accordance with time after applying negative bias illumination stress to thin film transistors according to Experimental Example 1 and Comparative Example.

### DETAILED DESCRIPTION

In the disclosure, the same reference numerals may refer to the same elements throughout. A thin film transistor according to exemplary embodiments of the inventive concept will be explained.

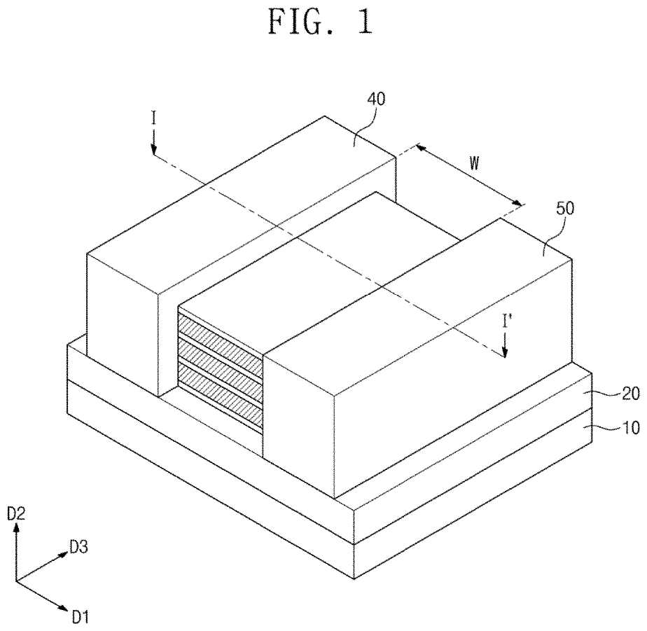

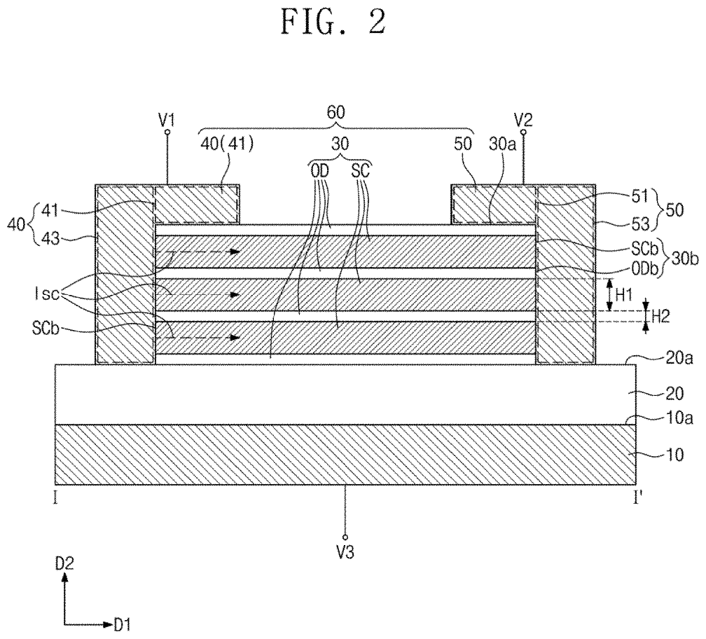

FIG. 1 is a perspective view of a thin film transistor according to exemplary embodiments of the inventive concept. FIG. 2 is a cross-sectional view cut along line I-I′ in FIG. 1.

Referring to FIG. 1 and FIG. 2, a thin film transistor 10 according to exemplary embodiments may include an insulating layer 20 and a stacked structure 60. More particularly, the stacked structure 60 may include a source electrode 40, a drain electrode 50 and a superlattice channel layer 30.

The substrate 10 may be a semiconductor substrate, a metal substrate, a glass substrate, or a flexible substrate. For example, the semiconductor substrate may include a silicon substrate including or not including impurities. The impurities may include, for example, a p-type dopant and an n-type dopant. The metal substrate may include, for example, aluminum (Al), chromium (Cr), copper (Cu), tantalum (Ta), titanium (Ti), molybdenum (Mo), tungsten (W) and/or alloys thereof. The flexible substrate may include a polymer substrate. The polymer substrate may include, for example, polyethylene terephthalate (PET) or polyimide (PI). The substrate 10 may play the role of the gate electrode of the thin film transistor according to exemplary embodiments. More particularly, a gate voltage V3 may be applied to the substrate 10. Detailed description on the operation of the thin film transistor will be given later.

The insulating layer 20 may be provided on the top 10a of the substrate 10. The insulating layer 20 may be disposed between the top 10a of the substrate 10 and the stacked structure 60. The insulating layer 20 may include an insulating material such as silicon oxide, silicon nitride, silicon oxynitride, metal oxide, metal nitride and/or mixtures thereof. In an embodiment, the insulating layer 20 may include aluminum oxide (Al₂O₃). The insulating layer 20 may play the role of the gate insulating layer of the thin film transistor according to exemplary embodiments. The insulating layer 20 may electrically insulate the stacked structure 60 and the substrate 10.

The stacked structure 60 may be provided on the top 20a of the insulating layer 20. The stacked structure 60 may include a superlattice channel layer 30, a source electrode 40, and a drain electrode 50.

The superlattice channel layer 30 may be provided on the top 20a of the insulating layer 20. The superlattice channel layer 30 may include alternately stacked semiconductor layers SC and organic layers OD. The semiconductor layers SC may be separately disposed from each other vertically by the organic layers OD. In an embodiment, the semiconductor layers SC may include first to third semiconductor layers separated vertically, and the organic layers OD may include first to fourth organic layers separated vertically. For example, the organic layers OD may be disposed at each of the lowermost and uppermost parts of the superlattice channel layer 30, and the semiconductor layers SC and the organic layers OD may be alternately and repeatedly provided in the superlattice channel layer 30. The bottom of the superlattice channel layer 30 may be the bottom of the lowermost organic layer OD, and the top 30a of the superlattice channel layer 30 may be the top of the uppermost organic layer OD. The lateral side 30b of the superlattice channel layer 30 may include the lateral sides ODb of the organic layers OD and the lateral sides SCb of the semiconductor layers SC. For example, the lateral sides ODb of the organic layers OD and the lateral sides SCb of the semiconductor layers Sc may be coplanar.

However, in FIG. 1 and FIG. 2, the superlattice channel layer 30 including three semiconductor layers SC is shown as a preferred embodiment, but the number of the semiconductor layers SC may be changed, without limitation. For example, the superlattice channel layer 30 may have a structure of organic layer OD/[semiconductor layer SC/organic layer OD]ₙ, [semiconductor layer SC/organic layer OD]ₙ, organic layer OD/[semiconductor layer SC/organic layer OD]ₙ₊₁/semiconductor layer SC, or [semiconductor layer SC/organic layer OD]ₙ₊₁/semiconductor layer SC. In this case, n may be 2 or 5.

Each of the semiconductor layers SC may be an n-type or p-type semiconductor layer. The semiconductor layers SC may include the same material, or different materials having the same conductive type. More particularly, each of the semiconductor layers SC may include a metal oxide semiconductor layer, a transition metal dichalcogenide (TMDC) layer, or an organic semiconductor layer. For example, the metal oxide semiconductor layer may include a binary metal oxide such as ZnO, SnO, SnO₂, TiO₂, In₂O₃, NiO, CoO, FeO, Cu₂O, CuO, and Cr₂O₃. In another embodiment, the metal oxide semiconductor layer may include a metal oxide including at least two among In, Ga and Zn, more particularly, indium gallium zinc oxide (IGZO). The TMDC layer may include, for example, NiS₂, WS₂, WSe₂, MoS₂, MoSe₂, or MoTe₂.

Each semiconductor layer SC may be an amorphous layer not including crystalline particles therein. A first thickness H1 in a second direction D2 of each semiconductor layer SC may be about 2 nm to about 10 nm, preferably, about 4 nm. Each semiconductor layer SC may be formed to the first thickness H1 and may have a relatively low dielectric constant. For example, the semiconductor layers SC with the first thickness H1 may have the dielectric constant of about 2 to about 10. In the disclosure, a first direction D1 may be a direction in parallel to the top 10a of the substrate 10. A second direction D2 may be a direction perpendicular to the top 10a of the substrate 10. A third direction D3 may be a direction which is in parallel to the top 10a of the substrate 10 while crossing the first direction D1.

The organic layers OD may be provided on the top 20a of the insulating layer 20. A second thickness H2 of each organic layer OD in the second direction D2 may be about 1 Å to about 1 nm, preferably, about 6 Å. A ratio of the thickness of any one among the organic layers OD with respect to the thickness of any one among the semiconductor layers SC may be about 0.1 to about 0.25. The organic layers OD may include a material having a band gap greater than the semiconductor layers SC. More particularly, each organic layer OD may include a material represented by [Formula A] below.

*—(X₁)ₐ(X₂)_{b}R(Y₁)_{c}(Y₂)_{d}—# [Formula A]

In Formula A, * is a part combined with the insulating layer 20 or a part combined with the top of an adjacent semiconductor layer SC. More particularly, * may be a part making a covalent bond with a metal element exposed to the top of the insulating layer 20 or a metal element exposed to the top of the semiconductor layer SC. # may be a part combined with the bottom of the semiconductor layer SC. More particularly, # may be a part making a covalent bond with a metal element exposed to the bottom of the semiconductor layer SC. X₁, X₂, Y₁, and Y₂ may be each independently O, S, Se, NH, or PH. More particularly, X₁ or X₂ may include an element having greater reactivity than Y₁ or Y₂. For example, X₁ or X₂ may be O, and Y₁ or Y₂ may be S, Se, NH, or PH. Each of a, b, c, and d may be 1 or 0, where a+b may be 1 or more, and c+d may be 1 or more.

In Formula A, R may include at least one aromatic group. In case where R includes two or more aromatic groups, the aromatic groups may be connected through connecting groups. The aromatic group may include an aromatic hydrocarbon group of 5 to 8 carbon atoms or a heterocyclic aromatic group of 3 to 7 carbon atoms. In an embodiment, the aromatic group may include a phenyl group.

The material represented by Formula A may include a material represented by Formula 1 below.

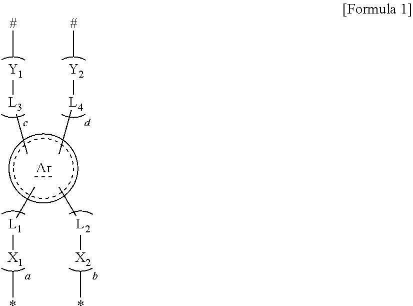

In Formula 1, X₁, X₂, Y₁, Y₂, a, b, c, and d are the same as defined in Formula A. R in Formula A may correspond to (L₁)(L₂)Ar(L₃)(L₄) in Formula 1. Ar is a functional group including at least one aromatic group, and if two or more aromatic groups are provided, the aromatic groups may be connected through connecting groups. The aromatic group may include an aromatic hydrocarbon group of 5 to 8 carbon atoms or a heterocycle aromatic group of 3 to 7 carbon atoms. In an embodiment, the aromatic group may include a phenyl group.

L₁ and L₂ may be functional groups connecting Ar with X₁ and X₂, respectively, and L₃ and L₄ may be functional groups connecting Ar with Y₁ and Y₂, respectively. Each of L₁, L₂, L₃ and L₄ may be an alkylene group of 1 to 3 carbon atoms.

The aromatic group may have a resonance structure. Accordingly, chemical bonds between the semiconductor layers SC and the organic layers OD may be stabilized. Accordingly, the generation of oxygen vacancy defect on the surface of the semiconductor layer SC which is adjacent to the organic layer OD may be restrained, and the operation reliability and electrical properties of the thin film transistor according to exemplary embodiments may be improved.

The materials represented by Formula A and Formula 1 may include, for example, any one among Compounds (1) to (17) below, or combinations of two or more thereof.

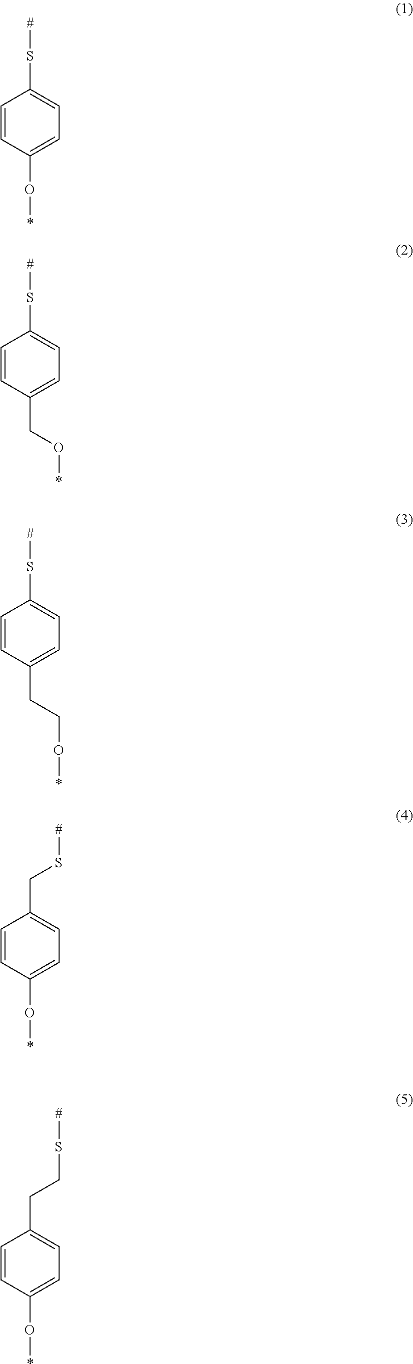

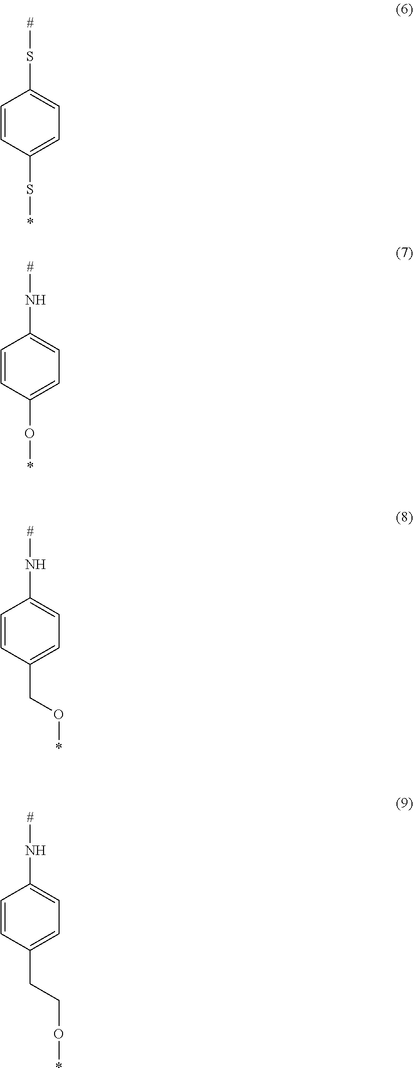

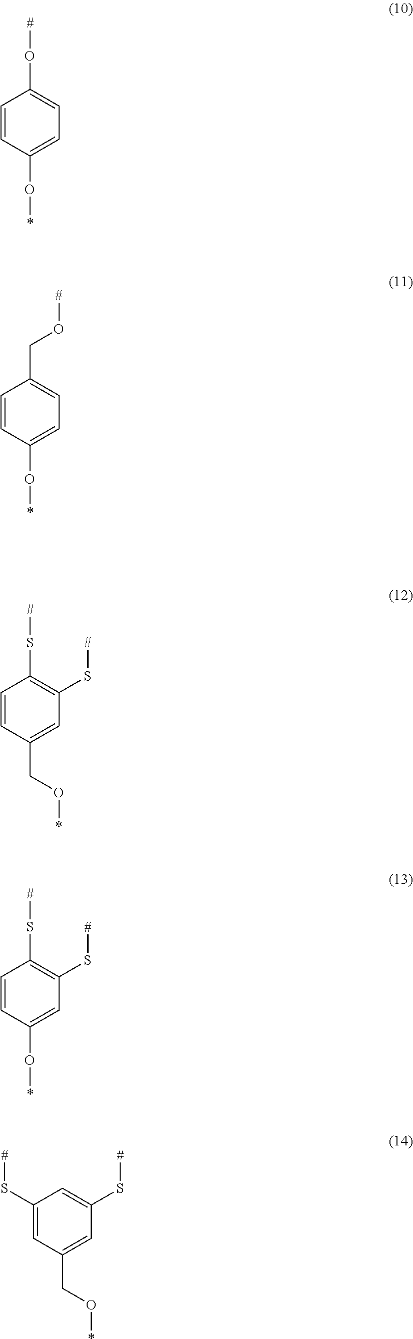

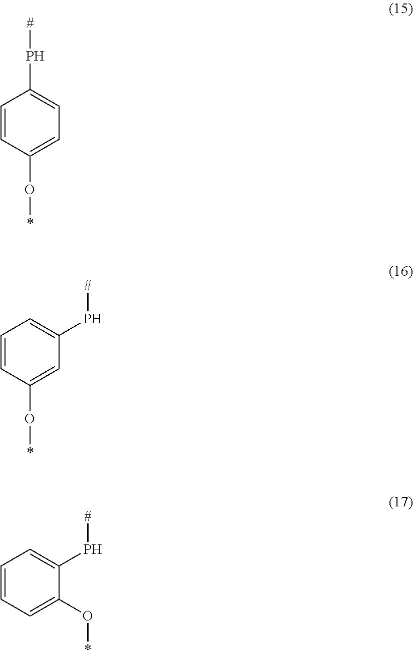

Molecules represented by Formula A and Formula 1 and adjacently disposed in the organic layer OD may be stabilized by a π-π bond between aromatic groups included in adjacent molecules.

The source electrode 40 and the drain electrode 50 may be provided on the top 20a of the insulating layer 20. The source electrode 40 and the drain electrode 50 may include a metal material or a metal oxide conductive layer. For example, the metal material may include aluminum (Al), neodymium (Nd), silver (Ag), chromium (Cr), titanium (Ti), tantalum (Ta), molybdenum (Mo) and/or alloys thereof, and the metal oxide conductive layer may include indium tin oxide (ITO).

The source electrode 40 and the drain electrode 50 may cover a pair of opposite lateral sides 30b of the superlattice channel layer 30, respectively. For example, the source electrode 40 and the drain electrode 50 may be oppositely disposed with the superlattice channel layer 30 therebetween. The source electrode 40 and the drain electrode 50 may have a symmetric structure with the superlattice channel layer 30 as the center. Each of the source electrode 40 and the drain electrode 50 may be extended in parallel to the lateral side 30b of the superlattice channel layer 30 and make contact with the lateral side 30b of the superlattice channel layer 30. More particularly, the source electrode 40 may include a first part 41 provided on the top of the superlattice channel layer 30 and a second part 43 which is connected with the first part 41 and extended in parallel to the lateral side 30b of the superlattice channel layer 30. From a plane point of view, the first part 41 of the source electrode 40 may cover the edge part of the top 30a of the superlattice channel layer 30, and the second part 43 of the source electrode 40 may cover one lateral side 30b of the superlattice channel layer 30. More particularly, the second part 43 of the source electrode 40 may make contact with each lateral side of the semiconductor layers SC.

The drain electrode 50 may include a first part 51 provided on the top 30a of the superlattice channel layer 30 and a second part 53 which is connected with the first part 51 and extended in parallel to the lateral side 30b of the superlattice channel layer 30. From a plane point of view, the first part 51 of the drain electrode 50 may cover the edge part of the top 30a of the superlattice channel layer 30, and the second part 53 of the drain electrode 50 may cover one lateral side 30b of the superlattice channel layer 30. More particularly, the second part 53 of the drain electrode 50 may make contact with each lateral side of the semiconductor layers SC.

The first part 41 of the source electrode 40 and the first part 51 of the drain electrode 50 may be separately disposed horizontally. The second part 43 of the source electrode 40 and the second part 53 of the drain electrode 50 may be oppositely disposed. The lateral side SCb of each semiconductor layer SC in the superlattice channel layer 30 may make contact with the second part 43 of the source electrode 40 and the second part 53 of the drain electrode 50.

Hereinafter, the operation properties of the thin film transistor according to exemplary embodiments will be explained continuously referring to FIG. 2.

Referring to FIG. 2, a first voltage, for example, a ground voltage may be applied to the source electrode 40. In the state of applying the first voltage V1 to the source electrode 40, a third voltage V3 having a value equal to or greater than a threshold voltage may be applied to the substrate 10, and a second voltage V2 may be applied to the drain electrode 50. Accordingly, the superlattice channel layer may be turned-on, charges may transfer between the source electrode and the drain electrode, and current may flow.

More particularly, in the superlattice channel layer 30, the organic layers OD may have a band gap greater than the semiconductor layers SC. For example, the band gap energy value of the organic layers OD may be about 6 eV to about 8 eV, and the band gap energy value of the semiconductor layers SC may be about 3 eV to about 4 eV. In case where the semiconductor layers SC are n-type semiconductor layers, the conduction band offset between the organic layers OD and the semiconductor layers SC may be about 1 eV to about 4 eV. In case where the semiconductor layers SC are p-type semiconductor layers, the valence band offset between the organic layers OD and the semiconductor layers SC may be about 1 eV to about 4 eV. Due to the offset, the conduction band or valence band of the semiconductor layers SC may be defined as a potential well. Due to the potential well, if the thin film transistor according to exemplary embodiments is turned-on, the charges in the semiconductor layers SC may be restricted in each semiconductor layer Sc and transfer horizontally. That is, if the thin film transistor according to exemplary embodiments is turned-on, current Isc in the superlattice channel layer 30 may flow from the source electrode 40 to the drain electrode 50 along each semiconductor layer SC horizontally.

The thin film transistor according to exemplary embodiments may use the superlattice channel layer 30 obtained by alternately stacking semiconductor layers SC and organic layers OD, which are formed in a small thickness, as the channel layer of the thin film transistor. Since the semiconductor layers SC and the organic layers OD have a small thickness, electric field by the third voltage V3 applied to the substrate 10 which plays the role of a gate electrode may influence each semiconductor layer SC in the superlattice channel layer 30. More particularly, in case of applying the third voltage V3 which is greater than the threshold voltage to the substrate 10, each semiconductor layer SC may be turned-on to flow charges in each semiconductor layer SC. Accordingly, the thin film transistor according to exemplary embodiments may have one threshold voltage and may have a structure in which a plurality of channel layers corresponds to one gate electrode.

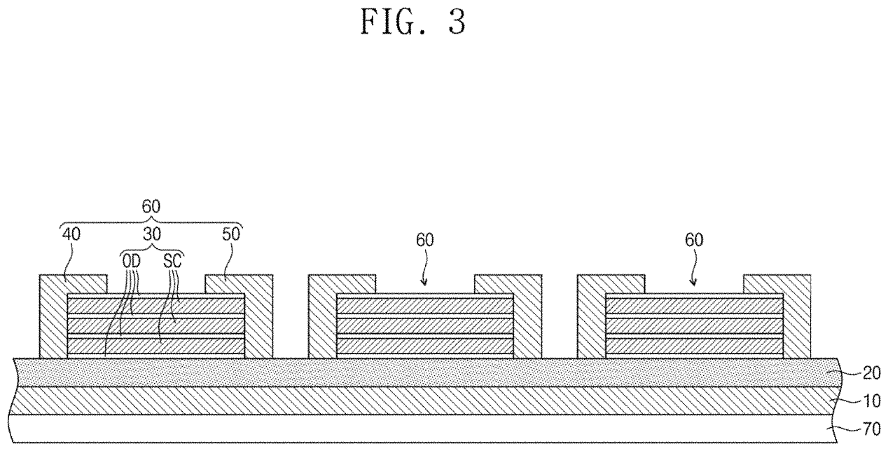

FIG. 3 is a diagram for explaining a thin film transistor according to exemplary embodiments of the inventive concept. Hereinafter, explanation in an overlapping range with the above-description will be omitted, and different features will be explained in detail.

Referring to FIG. 3, the thin film transistor according to exemplary embodiments may include a flexible film 70, a substrate 10, an insulating layer 20, and a plurality of stacked structures 60. More particularly, each stacked structure 60 may include a source electrode 40, a drain electrode 50 and a superlattice channel layer 30. The substrate 10, insulating layer 20 and stacked structures 60 may be substantially the same as those explained in FIG. 1 and FIG. 2, respectively.

A flexible film 70 may be provided. The flexible film 70 may be a film including a polymer. For example, the flexible film 70 may include a polymer such as polyethylene terephthalate (PET) and polyimide (PI), and may be flexibly bent in many directions.

On the flexible film 70, the substrate 10 and the insulating layer 20 may be provided. The substrate 10 may play the role of a gate electrode. On the flexible film 70, a plurality of stacked structures 60 may be disposed. The stacked structures 60 may be separated in horizontal direction and may be arranged in an array shape. Accordingly, a thin film transistor including a plurality of transistors and flexibly bent may be provided.

Hereinafter, a method of manufacturing a superlattice channel layer 30 will be explained in more detail.

An organic layer OD may be formed on the top 20a of an insulating layer 20 provided on a substrate 10 using a molecular layer deposition method. The formation of the organic layer OD may be performed in conditions of about 90° C. to about 120° C., preferably, about 100° C. to about 115° C.

A reaction chamber may be prepared, and a substrate 10 on which an insulating layer 20 is formed may be provided in the reaction chamber. A metal precursor may be dosed in the reaction chamber to react functional groups on the surface of the exposed insulating layer 20, oxygen atoms on the surface of an exposed semiconductor layer SC and chalcogen atoms on the surface of the exposed semiconductor layer SC with the metal precursor. The metal precursor may include, for example, an alkyl metal, a metal alkoxide, a metal halide, a metal hydroxide, and mixtures thereof. In case of dosing the metal precursor, the partial pressure of the metal precursor in the reaction chamber may be about 10 mTorr to about 30 mTorr. After dosing the metal precursor, a purge gas is supplied into the reaction chamber to purge an unreacted metal precursor and a reaction product. After the purging step, an organic precursor represented by Formula 2 below is dosed into the reaction chamber to react the organic precursor and the metal precursor.

H—(X₁)ₐ(X₂)_{b}R(Y₁)_{c}(Y₂)_{d}—H [Formula 2]

In Formula 2, X₁, X₂, Y₁, Y₂, a, b, c, and d are the same as defined in Formula A.

The organic precursor represented by Formula 2 may include an organic precursor represented by Formula 3 below.

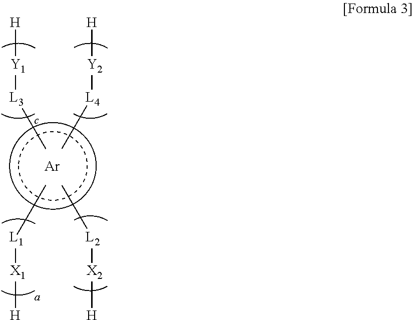

In Formula 3, X₁, X₂, Y₁, Y₂, a, b, c, and d may be the same as defined in Formula A, and Ar, L₁, L₂, L₃ and L₄ may be the same as defined in Formula 1.

The organic precursor represented by Formula 3 may include, for example, any one among Compounds (18) to (34) below, or combinations of two or more thereof.

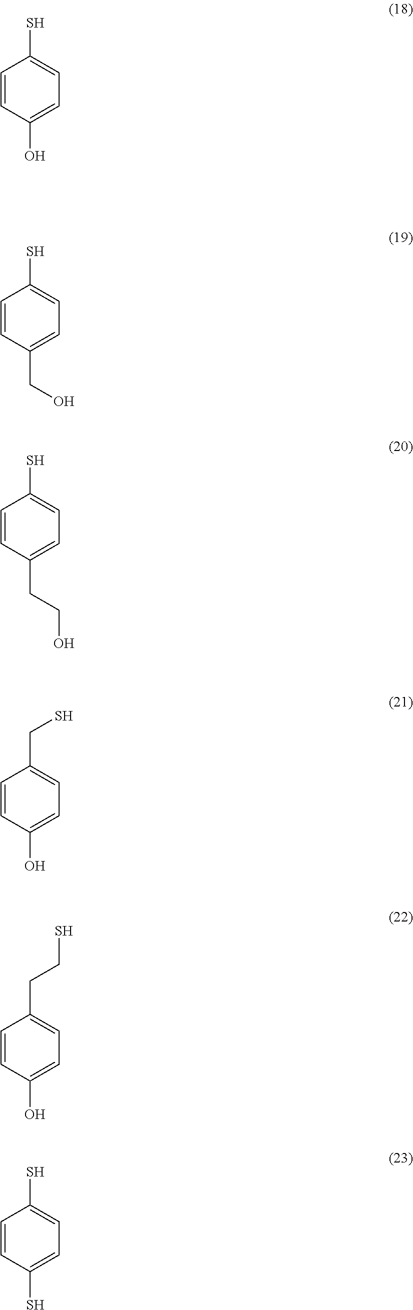 [SMILES: Oc1ccc(S)cc1 ; OCc1ccc(S)cc1 ; OCCc1ccc(S)cc1 ; Oc1ccc(CS)cc1 ; Oc1ccc(CCS)cc1 ; Sc1ccc(S)cc1]

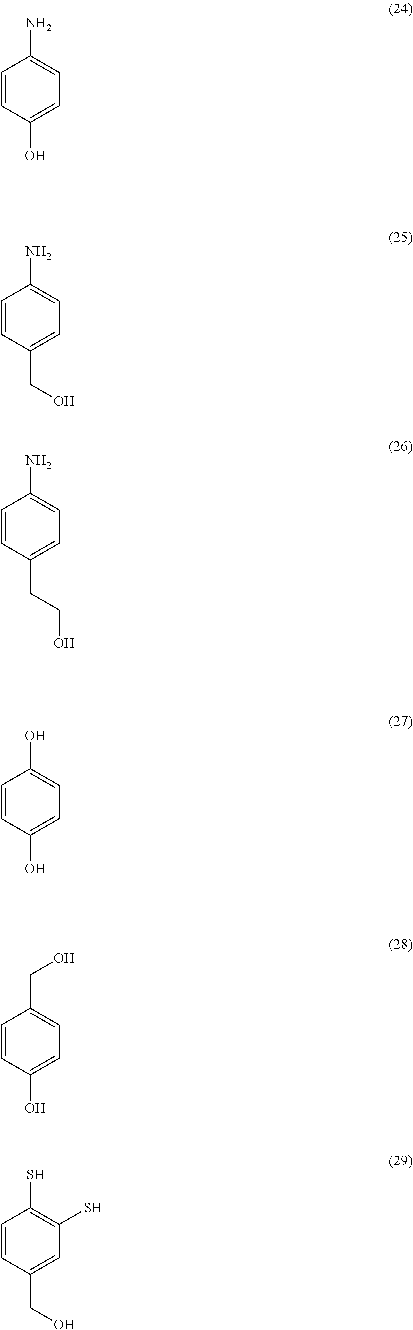 [SMILES: Nc1ccc(O)cc1 ; Nc1ccc(CO)cc1 ; Nc1ccc(CCO)cc1 ; Oc1ccc(O)cc1 ; OCc1ccc(O)cc1 ; OCc1ccc(S)c(S)c1]

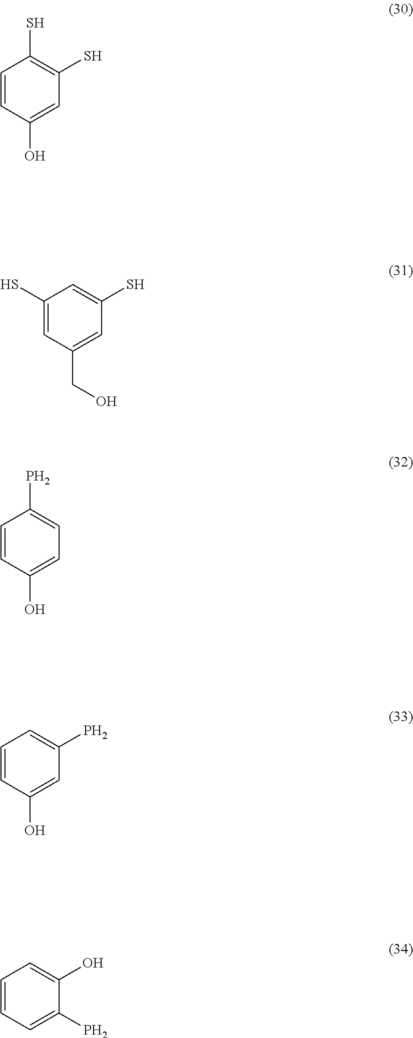

In case where the organic precursor and the metal precursor react, a metal element in the metal precursor and X₁ or X₂ of the organic precursor may be combined via a covalent bond. After dosing the organic precursor, a purge gas is supplied into the reaction chamber to purge an unreacted organic precursor and a reaction product. The above-described process (unit cycle) may be repeated once to three times to form an organic layer OD.

On the organic layer OD, a semiconductor layer SC may be formed. In case of omitting the organic layer OD, the semiconductor layer SC may be formed on the top 20a of the insulating layer 20 which is formed on the substrate 10. The semiconductor layer SC may be formed using an atomic layer deposition method. The semiconductor layer Sc may be formed in conditions of about 90° C. to about 120° C., preferably, about 100° C. to about 115° C.

A reaction chamber may be prepared, and a substrate 10 on which an organic layer OD is formed may be provided in the reaction chamber. A metal precursor may be dosed in the reaction chamber to react functional groups on the surface of an exposed organic layer OD (# part of Formula A or Formula 1) or, in case of omitting the organic layer OD, on the surface of an exposed insulating layer 20 with the metal precursor. The metal precursor may include, for example, an alkyl metal, a metal alkoxide, a metal hydroxide, and mixtures thereof. More particularly, in case where the semiconductor layer SC includes ZnO, the metal precursor may be diethyl zinc, but may be modified without limitation. In case of dosing the metal precursor, the partial pressure of the metal precursor in the reaction chamber may be about 10 mTorr to about 30 mTorr. After dosing the metal precursor, a purge gas may be supplied into the reaction chamber to purge an unreacted metal precursor and a reaction product. After the purging step, an oxidizing agent or chalcogenizer is dozed in the reaction chamber so that the metal precursor may react with the oxidizing agent or chalcogenizer. The oxidizing agent may include H₂O, and the chalcogenizer may include H₂S, H₂Se, or H₂Te. The above-described process (unit cycle) may be repeated 10 times to 50 times, preferably, 25 times to 30 times to form a semiconductor layer SC. In an embodiment, if the semiconductor layer SC includes ZnO, a growth thickness per unit cycle may be about 10 Å to about 20 Å. Accordingly, the semiconductor layer SC may have a thickness of about 2 um to about 10 um in a second direction D2. As described above, the formation of the organic layer OD and the formation of the semiconductor layer SC may be repeated to manufacture the superlattice channel layer 30 of the thin film transistor according to exemplary embodiments.

Hereinafter, the manufacture of the thin film transistor according to exemplary embodiments and evaluation results thereof will be explained.

### Experimental Example 1

A p-type silicon wafer was cut and used as a substrate. A chemical washing process was carried out with respect to the substrate to remove contaminating materials on the substrate. For the chemical washing process, HNO₃, NH₄OH and HCl were used. After carrying out the chemical washing process, a thin protective layer was formed on the substrate. The protective layer may be a silicon oxide layer.

On the substrate, an insulating layer was formed by carrying out an atomic layer deposition process (ALD). More particularly, the substrate was loaded in a chamber, trimethyl aluminum (TMA, Aldrich, 97%) which is an aluminum precursor was supplied on the substrate for about 2 seconds, and an argon purge gas was supplied for about 20 seconds to purge reaction by-products and residual reactants. Then, H₂O was supplied for about 2 seconds, and argon was supplied for about 40 seconds to form an insulating layer which is an aluminum oxide layer. The unit cycle of an atomic layer deposition process for forming the insulating layer included supplying of the trimethyl aluminum for about 2 seconds, supplying of the purge gas for about 20 seconds, supplying of the H₂O for about 2 seconds, and supplying of the purge gas for about 40 seconds. The unit cycle was repeated many times to form an insulating layer having a thickness of about 15 nm. During forming the insulating layer, the flowing amount of the argon gas was about 100 sccm, and the temperature conditions of the chamber was maintained to about 110° C. or less.

An organic layer was formed on the insulating layer by carrying out a molecular layer deposition process (MLD). More particularly, a substrate on which an insulating layer is formed was loaded in a chamber, diethyl zinc (Aldrich, 97%) which is a zinc precursor was supplied on the insulating layer for about 2 seconds, and an argon purge gas was supplied for about 20 seconds to purge reaction by-products and residual reactants. Then, 4-mercaptophenol (4MP, Aldrich, 97%) was supplied for about 20 seconds, and an argon purge gas was supplied for about 200 seconds to purge reaction by-products and residual reactants. During forming the organic layer, diethyl zinc (DEZ) and 4-mercaptophenol (4MP) were vaporized at 20° C. and 75° C., respectively, the flowing amount of the argon gas was about 100 sccm, and temperature conditions of the chamber of 110° C. or less were maintained. The unit cycle of a molecular layer deposition process for forming the organic layer included supplying of the diethyl zinc for about 2 seconds, supplying of the purge gas for about 20 seconds, supplying of the 4MP for about 20 seconds and supplying of the argon for about 200 seconds. The unit cycle was carried out once to form an organic layer having a thickness of about 6 Å.

On the organic layer, an atomic layer deposition process (ALD) was carried out to form a semiconductor layer. More particularly, the substrate on which the organic layer is formed was loaded in a chamber, diethyl zinc (Aldrich, 97%) was supplied on the organic layer for about 2 seconds, and an argon purge gas was supplied for about 20 seconds to purge reaction by-products and residual reactants. H₂O was supplied for about 2 seconds to form a semiconductor layer which is a ZnO layer, and an argon purge gas was supplied for about 40 seconds to purge reaction by-products and residual reactants. During forming the semiconductor layer, the flowing amount of the argon gas was about 100 sccm, and the temperature conditions of the chamber was maintained to about 110° C. or less. The unit cycle of an atomic layer deposition process for forming the semiconductor layer included supplying of the diethyl zinc for about 2 seconds, supplying of the purge gas for about 20 seconds, supplying of the H₂O for about 2 seconds, and supplying of the purge gas for about 40 seconds. The unit cycle was repeated many times to form a semiconductor layer having a thickness of about 4 nm.

Then, the formation of the organic layer and the formation of the semiconductor layer were additionally carried out twice further, and an organic layer was formed on the top of the uppermost semiconductor layer to manufacture a superlattice channel layer in which the organic layers and the semiconductor layers were alternately stacked. The cross-sectional view of the superlattice channel layer thus manufactured was observed with a transmission electron microscope (TEM), and the semiconductor layer was observed through an X-ray diffraction analysis method.

On the superlattice channel layer, a patterning process was carried out by using a photolithography method so that the width of the superlattice channel layer became about 500 um. An aluminum layer with a thickness of about 70 um was deposited using a thermal evaporation method on the patterned superlattice channel layer to form a source electrode and a drain electrode and to complete a thin film transistor.

### Experimental Example 2

A thin film transistor was formed by the same method as in Experimental Example 1 except for changing the thickness of the semiconductor layer to about 3 nm.

### Experimental Example 3

A thin film transistor was formed by the same method as in Experimental Example 1 except for changing the thickness of the semiconductor layer to about 5 nm.

Table 1 shows field mobility and on-off current ratios in accordance with the thickness of the semiconductor layer for the thin film transistors manufactured in Experimental Example 1 to Experimental Example 3.

TABLE 1

| Thickness of | 3 nm | 4 nm | 5 nm |
|---|---|---|---|
| semiconductor | (Experimental | (Experimental | (Experimental |
| layer | Example 2) | Example 1) | Example 3) |
| Field mobility | 28.75 | 71.04 | 49.51 |
| (cm²/V · s) | | | |
| On-off current | 1.1*10⁶ | 1.7*10⁷ | 1.3*10⁵ |
| ratio | | | |
| (Iₒₙ/I_{off}) | | | |

Referring to Table 1, in Experimental Example 1 in which the thickness of the semiconductor layer was about 4 nm, the field mobility and on-off current ratio were the values of 71.04 and 1.7*10⁷, respectively, and were confirmed to higher than those of Experimental Example 2 and Experimental Example 3. Accordingly, the optimum thickness of the semiconductor layer was about 4 nm, and if the thickness is smaller or greater than this value, electrical properties may be deteriorated.

### Experimental Example 4

A thin film transistor was manufactured by the same method as in Experimental Example 1 except for carrying out the unit cycle of a molecular layer deposition process for forming an organic layer three times to form the organic layer having a thickness of about 18 Å.

### Experimental Example 5

A thin film transistor was manufactured by the same method as in Experimental Example 1 except for carrying out the unit cycle of a molecular layer deposition process for forming an organic layer five times to form the organic layer having a thickness of about 30 Å.

### Experimental Example 6

A thin film transistor was manufactured by the same method as in Experimental Example 1 except for carrying out the unit cycle of a molecular layer deposition process for forming an organic layer seven times to form the organic layer having a thickness of about 42 Å.

Table 2 shows field mobility and on-off current ratios in accordance with the thickness of the organic layer for the thin film transistors manufactured in Experimental Example 4 to Experimental Example 6.

TABLE 2

| Thickness of | 6 Å | 18 Å | 30 Å | 40 Å |
|---|---|---|---|---|
| organic | (Experimental | (Experimental | (Experimental | (Experimental |
| layer | Example 1) | Example 4) | Example 5) | Example 6) |
| Field mobility | 45.22 | 38.49 | 15.76 | 12.63 |
| (cm²/V · s) | | | | |
| On-off current | 2.8*10⁷ | 2.5*10⁶ | 2.3*10⁴ | 2.0*10⁵ |
| ratio | | | | |
| (Iₒₙ/I_{off}) | | | | |

Referring to Table 2, it was confirmed that with the decrease of the thickness of the organic layer, the field mobility and on-off current ratio values were increased. Since the organic layer has high specific resistance, if the thickness of the organic layer increases, the internal resistance of the thin film transistor may increase, and the field mobility may decrease. Accordingly, the optimum thickness of the organic layer is about 6 Å (once of the unit cycle of a molecular layer deposition process), and if the thickness is greater than this value, electrical properties may be deteriorated.

### Experimental Example 7

A superlattice channel layer having a three-layer structure of [organic layer/semiconductor layer/organic layer] was formed, wherein the formation of the organic layer and the semiconductor layer followed the same method as in Experimental Example 1.

### Experimental Example 8

A superlattice channel layer having a five-layer structure of [organic layer/(semiconductor layer/organic layer)₂] was formed, wherein the formation of the organic layer and the semiconductor layer followed the same method as in Experimental Example 1.

### Experimental Example 9

A superlattice channel layer having a nine-layer structure of [organic layer/(semiconductor layer/organic layer)₄] was formed, wherein the formation of the organic layer and the semiconductor layer followed the same method as in Experimental Example 1.

Table 3 shows field mobility and on-off current ratios in accordance with the structure of the superlattice channel layer for the thin film transistors manufactured in Experimental Example 7 to Experimental Example 9.

TABLE 3

| Number of | One | Two | Three | Four |
|---|---|---|---|---|
| semiconductor | (Experimental | (Experimental | (Experimental | (Experimental |
| layers | Example 7) | Example 8) | Example 1) | Example 9) |
| Field mobility | 22.00 | 45.22 | 71.04 | 38.29 |
| (cm²/V · s) | | | | |
| On-off current | 4.8*10⁷ | 2.8*10⁷ | 1.7*10⁷ | 3.0*10⁵ |
| ratio | | | | |
| (Iₒₙ/I_{off}) | | | | |

Referring to Table 3, the highest field mobility value of 71.04 was observed for Experimental Example 1 in which the number of the semiconductor layers stacked in the superlattice channel layer was three. The on-off current ratio was the highest for Experimental Example 7. However, considering that the field mobility is the most important factor for evaluating the electrical properties of the thin film transistor, it could be confirmed that the optimum number of the semiconductor layer in the superlattice channel layer was three. If the number is smaller or greater than this value, the electrical properties may be deteriorated.

### Experimental Example 10

A thin film transistor was manufactured by the same method as in Experimental Example 1 except for maintaining the temperature conditions in a chamber to about 90° C. during forming a semiconductor layer.

### Experimental Example 11

A thin film transistor was manufactured by the same method as in Experimental Example 1 except for maintaining the temperature conditions in a chamber to about 100° C. during forming a semiconductor layer.

### Experimental Example 12

A thin film transistor was manufactured by the same method as in Experimental Example 1 except for maintaining the temperature conditions in a chamber to about 110° C. during forming a semiconductor layer.

### Experimental Example 13

A thin film transistor was manufactured by the same method as in Experimental Example 1 except for maintaining the temperature conditions in a chamber to about 120° C. during forming a semiconductor layer.

Table 4 shows field mobility and on-off current ratios in accordance with the deposition temperature of the semiconductor layer in Experimental Example 10 to Experimental Example 13.

TABLE 4

| | 90° C. | 100° C. | 110° C. | 120° C. |
|---|---|---|---|---|
| Temperature in | (Experimental | (Experimental | (Experimental | (Experimental |
| chamber | Example 10) | Example 11) | Example 12) | Example 13) |
| Field mobility | 54.08 | 64.83 | 71.04 | 55.15 |
| (cm²/V · s) | | | | |
| On-off current | 6.9*10⁶ | 4.8*10⁶ | 1.7*10⁷ | 9.3*10⁵ |
| ratio | | | | |
| (Iₒₙ/I_{off}) | | | | |

Referring to Table 4, in Experimental Example 12 in which the semiconductor layer was formed at temperature conditions of about 110° C., the field mobility and on-off current ratio values were 71.04 and 1.7*10⁷, respectively, and showed higher electrical properties than those of Experimental Example 10, Experimental Example 11 and Experimental Example 13. Accordingly, the optimum temperature conditions for forming the semiconductor layer were about 110° C., and if the temperature is higher or lower than this value, electrical properties may be deteriorated.

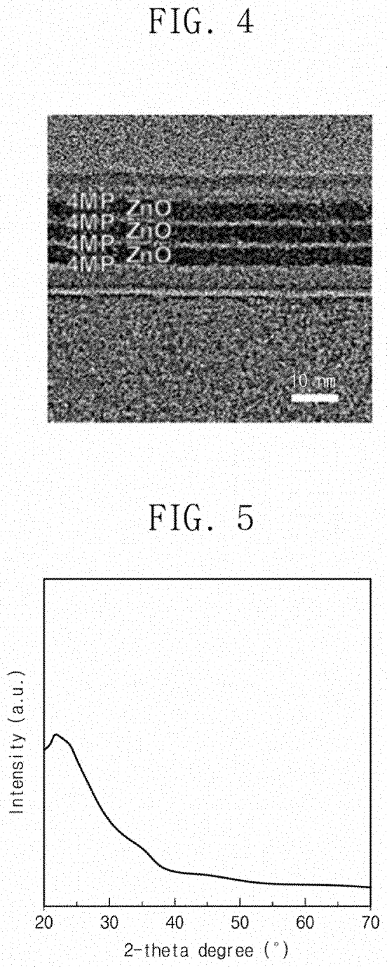

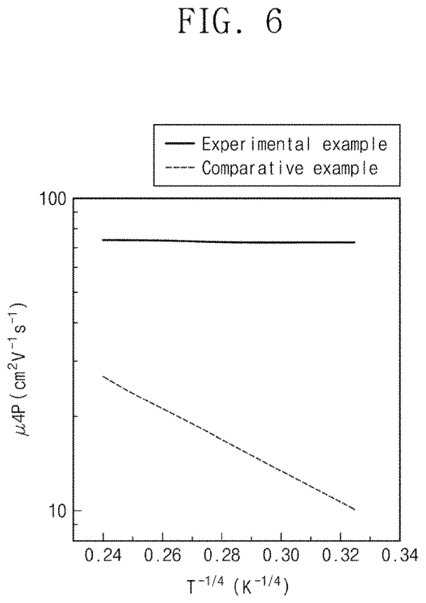

FIG. 4 is a photographic image observed with a transmission electron microscope on the cross-section of the superlattice channel layer according to Experimental Example 1. FIG. 5 shows analysis results on the semiconductor layer of the superlattice channel layer according to Experimental Example 1 through an X-ray diffraction observation method.

Referring to FIG. 4, it could be confirmed that the superlattice channel layer formed by Experimental Example 1 has an alternately stacked structure of organic layers (4MP) and semiconductor layers (ZnO). Referring to FIG. 5, it could be confirmed that the superlattice channel layer formed by Experimental Example 1 is amorphous semiconductor.

### Comparative Example

A thin film transistor was manufactured using the channel layer of a single material (ZnO) having the same thickness as the superlattice channel layer formed in Experimental Example 1. The formation of the substrate, the insulating layer, the source electrode and the drain electrode was the same as in Experimental Example 1.

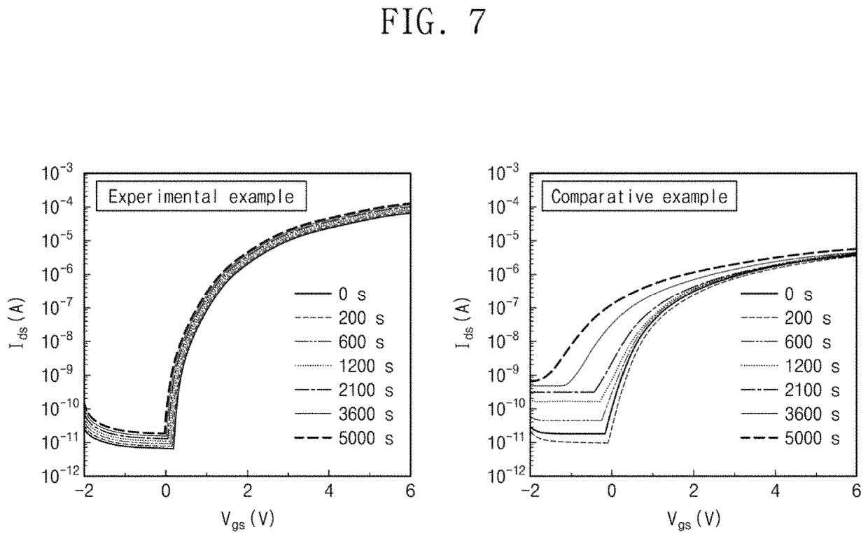

FIG. 6 is a graph showing field mobility in accordance with operation temperature conditions of thin film transistors according to Experimental Example 1 and Comparative Example.

Referring to FIG. 6, field mobility was observed at different operation temperature conditions for the thin film transistors according to Experimental Example 1 and Comparative Example. The filed mobility of the thin film transistor of Comparative Example including the channel layer of the single material (ZnO) was rapidly reduced with the decrease of the temperature, and it could be confirmed that charges transferred according to a hopping mechanism. Meanwhile, the thin film transistor of Experimental Example 1, including the superlattice channel layer showed constant field mobility irrespective of the temperature, and it was confirmed that charges transferred according to a band-like charge conduction mechanism.

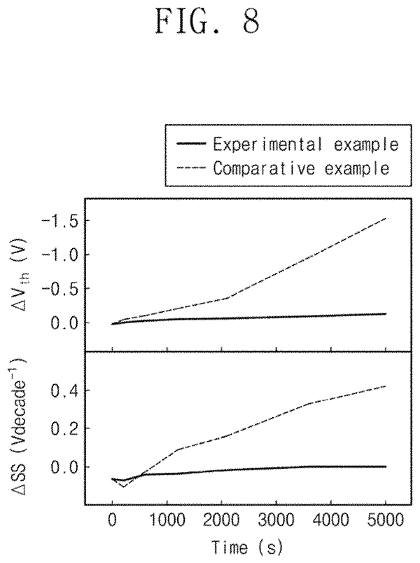

FIG. 7 and FIG. 8 show graphs showing transfer properties, threshold voltage and charge mobility in accordance with time after applying negative bias illumination stress to thin film transistors according to Experimental Example 1 and Comparative Example.

Referring to FIG. 7 and FIG. 8, the thin film transistor according to Comparative Example showed significant deterioration of transfer properties, threshold voltage and charge mobility according to the increase of time for applying negative bias illumination stress. On the contrary, it was confirmed that the thin film transistor according to Experimental Example 1 maintained stable performance through stress was applied for about 5000 seconds. Accordingly, it could be found that since the thin film transistor of Experimental Example 1 included the superlattice channel layer, stabilization effects were improved, and the operation reliability of the thin film transistor may be improved when compared with the channel layer of a single material.

The thin film transistor according to the inventive concept may include a superlattice channel layer in which numbers of organic layers and semiconductor layers are alternately stacked. Accordingly, the thin film transistor according to an embodiment has higher field mobility than a case where a semiconductor layer with a single material is utilized as the channel layer of a transistor, and a thin film transistor with improved electrical properties may be provided.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A thin film transistor, comprising:
a substrate;
an insulating layer provided on the substrate;
a superlattice channel layer provided on the insulating layer; and
a source electrode and a drain electrode configured to cover a pair of opposite lateral surfaces of the superlattice channel layer, wherein
the superlattice channel layer comprises alternately stacked semiconductor layers and organic layers,
a thickness of each semiconductor layer being greater than about 3 nm to less than about 5 nm, and
a thickness of each organic layer being about 1 Å to about 1 nm.

2. The thin film transistor of claim 1, wherein
the semiconductor layers comprise first to third semiconductor layers, which are separated vertically,
the organic layers comprise first to fourth organic layers, which are separated vertically, and
a ratio of a thickness of any one among the organic layers with respect to a thickness of any one among the semiconductor layers is about 0.1 to about 0.25.

3. The thin film transistor of claim 1, wherein the semiconductor layers comprise a metal oxide or a transition metal dichalcogenide.

4. The thin film transistor of claim 1, wherein the organic layer comprises a material represented by the following Formula 1: 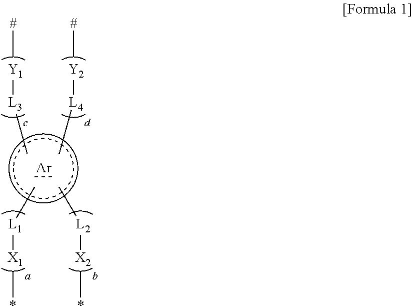
in Formula 1, X₁, X₂, Y₁, and Y₂ are each independently O, S, Se, NH, or PH, * is a part combined with a top of the insulating layer or a top of any one among adjacent semiconductor layers, # is a part combined with a bottom of any other one among adjacent semiconductor layers, each of a, b, c, and d is 1 or 0, where a+b is 1 or more, and c+d is 1 or more, Ar is a functional group comprising at least one aromatic group, and each of L₁, L₂, L₃ and L₄ is an alkylene group of 1 to 3 carbon atoms.

5. The thin film transistor of claim 1, wherein
the source electrode comprises a first part provided on a top of the superlattice channel layer, and a second part connected with the first part and extended in parallel to the lateral surface of the superlattice channel layer, and
the second part of the source electrode is in contact with the lateral surfaces of the semiconductor layers.

6. The thin film transistor of claim 5, wherein
the drain electrode comprises a first part provided on the top of the superlattice channel layer, and a second part connected with the first part and extended in parallel to the lateral surface of the superlattice channel layer,
the first part of the source electrode and the first part of the drain electrode are separately disposed horizontally, and
a separating distance between the first part of the source electrode and the first part of the drain electrode is about 200 um to about 400 um.

7. The thin film transistor of claim 1, wherein the superlattice channel layer comprises any one among structures of organic layer/[semiconductor layer/organic layer]ₙ, [semiconductor layer/organic layer]ₙ, organic layer/[semiconductor layer/organic layer]ₙ₊₁/semiconductor layer, and [semiconductor layer/organic layer]ₙ₊₁/semiconductor layer, where n is 2 or 3.

8. The thin film transistor of claim 1, wherein
the thin film transistor has one threshold voltage, and
with the application of a higher voltage than the threshold voltage to the substrate, charges are configured to move horizontally along each semiconductor layer.

9. The thin film transistor of claim 1, wherein
the semiconductor layers are amorphous semiconductor, and
a dielectric constant of each semiconductor layer is about 2 to about 6.

10. The thin film transistor of claim 1, wherein
a flexible film provided on a bottom of the substrate is further comprised,
numbers of the superlattice channel layers are provided on the flexible film, and
the flexible film comprises polyethylene terephthalate (PET) or polyimide (PI).
